(19) United States
(12) Patent Application Publication
(10) Pub. No.: US 2025/0271473 A1
(43) Pub. Date: Aug. 28, 2025

(54) SELF-MONITORING HIGH ACCURACY RADIO FREQUENCY POWER SENSOR

(71) Applicant: Bird Technologies Group Inc., Solon, OH (US)

(72) Inventors: Amr ABDELMONEM, Northbrook, IL (US); Martin DUMMERMUTH, Chagrin Falls, OH (US); Timothy HOLT, Chardon, OH (US); Daniel HOSHIKO, University Heights, OH (US); Jeffrey KLIS, Chardon, OH (US); Melvin HOLT, JR., Cleveland Heights, OH (US)

(21) Appl. No.: 18/586,217

(22) Filed: Feb. 23, 2024

(51) Int. Cl. G01R 21/01; G01R 21/14; G01R 35/00

(52) U.S. Cl. CPC G01R 21/01; G01R 21/14; G01R 35/005

(57) ABSTRACT

Disclosed is a radio frequency (RF) power sensor having measurement uncertainty of less than about ±0.3%, which is achieved through the use of cross-correlation for reduction of uncertainty. The power sensor may have multiple couplers, multiple detectors, and at least one analog to digital converter. Also disclosed is a method for operating the power sensor to realize measurement uncertainty of less than about ±0.3% due to the uncorrelated nature of the measurements, as well as one or more of identifying the need for power sensor calibration, extending the time between calibrations, and predicting remaining time until calibration is required.

### FIELD OF THE INVENTION

This application is directed to radio frequency (RF) power measurement. More specifically, to an in-line RF power sensor.

### BACKGROUND OF THE INVENTION

Accuracy of RF power measurement is extremely important, especially in sensitive applications such as semiconductor fabrication.

### BRIEF SUMMARY OF THE INVENTION

According to one aspect of the present invention, a radio frequency (RF) power sensor is provided. The RF power sensor has a measurement uncertainty of less than about ±0.3%, wherein the power sensor is a thru-line power sensor.

In another aspect of the invention, the power sensor is configured to measure an RF power level greater than or equal to about 1 watt. The measurement uncertainty of less than about ±0.3% is achieved using cross-correlation.

In another aspect of the invention, the RF power sensor is comprised of a transmission line and at least one forward directional coupler circuit for measuring power on the transmission line using cross-correlation for reduction of uncertainty.

In another aspect of the invention, the RF power sensor is comprised of at least three forward directional coupler circuits for measuring power on the transmission line using cross-correlation for reduction of uncertainty. The individual measurements of the at least three forward directional couplers circuits are averaged together, thereby producing an aggregate average forward power measurement and providing to a user as a forward power measurement of the RF power sensor.

In another aspect of the invention, the RF power sensor calculates a percentage error magnitude for each of the at least three forward directional coupler circuits using the aggregate average forward power measurement and the individual measurements of the at least three forward directional coupler circuits.

In another aspect of the invention, the percentage error magnitude for each forward directional coupler circuit is compared to a predetermined percent difference threshold on an individual basis. The forward directional coupler circuit is considered to be out of calibration, when the percentage error magnitude is greater than a predetermined percent difference threshold.

In another aspect of the invention, individual measurements from the out of calibration directional coupler circuits are excluded from the aggregate average forward power measurements.

In another aspect of the invention, the RF power sensor is considered to be out of calibration, when a number of forward coupler circuits considered to be out of calibration is greater than a predetermined out of calibration forward circuit threshold, and the RF power sensor informs a user when the RF power sensor is out of calibration.

In another aspect of the invention, the RF power sensor calculates a trend of the percentage error magnitudes over time to estimate a time until calibration of the RF power sensor is needed.

In another aspect of the invention, at least one environmental correction is applied to each of the individual measurements of the at least three forward directional couplers circuits.

In another aspect of the invention, the environmental corrections correct for one or more of temperature, humidity, frequency, voltage standing waves, and/or a center conductor position error of the transmission line.

In another aspect of the invention, the correction for the temperature is determined using a temperature sensor of the RF power sensor and a temperature characterization curve; the correction for the humidity is determined using a humidity sensor of the RF power sensor and a humidity characterization curve; the correction for frequency is determined using a non-directional coupler of the RF power sensor, a prescaler of the RF power sensor, and a frequency characterization curve; the correction for the voltage standing waves is determined using a spatial position of a forward coupler of each the forward directional coupler circuits, the measurements of the forward directional coupler circuits, a spatial position and a measurement of a reflected directional coupler of the RF power sensor, and a measurement of the reflected directional coupler; and the center conductor position error correction is determined using a spatial position longitudinally along the transmission line and rotationally around the transmission line for each of the forward couplers of the forward directional coupler circuits, and the measurements of the forward directional coupler circuits.

In another aspect of the invention, the RF power sensor further comprising a real-time clock. The RF power sensor uses the real-time clock to determine if a predetermined recommended calibration time interval has elapsed since a last calibration.

According to yet another aspect of the invention, a method for making an RF power measurement comprising: providing a power sensor having measurement uncertainty of less than about ±0.3%. The power sensor is a thru-line power sensor.

In another aspect of the invention, the RF power sensor is comprised of a transmission line and at least one forward directional coupler circuit for measuring power on the transmission line. Cross-correlation is used to achieve the uncertainty of less than about ±0.3%.

In another aspect of the invention, the RF power sensor is comprised of at least three forward directional coupler circuits for measuring power on the transmission line using cross-correlation for reduction of uncertainty. The method further comprises: obtaining individual measurements of the at least three forward directional coupler circuits and averaging the individual measurements, thereby producing an aggregate average forward power measurement, providing the aggregate average forward power measurement to a user as a forward power measurement of the RF power sensor.

In another aspect of the invention, the method further includes, calculating a percentage error magnitude for each of the at least three forward directional coupler circuits using the aggregate average forward power measurement and the individual measurements of the at least three forward directional coupler circuits.

In another aspect of the invention, the method further includes, comparing the percentage error magnitude for each forward directional coupler circuit to a predetermined percent difference threshold on an individual basis, wherein the forward directional coupler circuit is considered to be out of calibration, when the percentage error magnitude is greater than a predetermined percent difference threshold.

In another aspect of the invention, the method further includes, excluding from the aggregate average forward power measurements, the individual measurements of the out of calibration directional coupler circuits.

In another aspect of the invention, the method further includes, wherein the RF power sensor is considered to be out of calibration, when a number of forward coupler circuits considered to be out of calibration is greater than a predetermined out of calibration forward circuit threshold, and informing a user when the RF power sensor is out of calibration.

In another aspect of the invention, the method further includes calculating a trend of the percentage error magnitudes over time to estimate a time until calibration of the RF power sensor is needed, and informing a user of the estimate of the time until calibration of the RF power sensor is needed.

In another aspect of the invention, the method further includes applying at least one environmental correction to each of the individual measurements of the at least three forward directional couplers circuits.

In another aspect of the invention, the environmental corrections correct for one or more of temperature, humidity, frequency, voltage standing waves, and/or a center conductor position error of the transmission line.

In another aspect of the invention, the method further includes, the correction for the temperature is calculated using a temperature sensor of the RF power sensor and a temperature characterization curve. The correction for the humidity is calculated using a humidity sensor of the RF power sensor and a humidity characterization curve. The correction for frequency is calculated using a non-directional coupler of the RF power sensor, a prescaler of the RF power sensor, and a frequency characterization curve. The correction for the voltage standing waves is calculated using a spatial position of a forward coupler of each the forward directional coupler circuits, the measurements of the forward directional coupler circuits, a spatial position and a measurement of a reflected directional coupler of the RF power sensor, and a measurement of the reflected directional coupler. The center conductor position error correction is calculated using a spatial position longitudinally along the transmission line and rotationally around the transmission line for each of the forward couplers of the forward directional coupler circuits, and the measurements of the forward directional coupler circuits.

In another aspect of the invention, the RF power sensor is further comprised of a real-time clock, the method further comprising using the real-time clock to determine if a predetermined recommended calibration time interval has elapsed since a last calibration.

According to yet another aspect of the invention, an RF power sensor having a measurement uncertainty of less than about ±0.3%, comprising, a transmission line; a processor; a memory communicatively connected to the processor, the memory storing instructions that, when executed by the processor, cause the processor to: measure power on the transmission line with a measurement uncertainty of the less than about ±0.3%. The RF power sensor is a thru-line power sensor.

In another aspect of the invention, the power sensor is configured to measure an RF power level greater than or equal to about 1 watt. The measurement uncertainty of less than about ±0.3% is achieved using cross-correlation.

In another aspect of the invention, the RF power sensor also includes at least one forward directional coupler circuit for measuring power on the transmission line using cross-correlation for reduction of uncertainty.

In another aspect of the invention, the RF power sensor is comprised of at least three forward directional coupler circuits, the memory storing instructions that, when executed by the processor, cause the processor to: use cross-correlation for reduction of uncertainty, calculate an aggregate average forward power measurement using individual measurements of the at least three forward directional couplers circuits, and provide the aggregate average forward power measurement to a user as a forward power measurement of the RF power sensor.

In another aspect of the invention, the memory storing instructions that, when executed by the processor, cause the processor to: calculate a percentage error magnitude for each of the at least three forward directional coupler circuits using the aggregate average forward power measurement and the individual measurements of the at least three forward directional coupler circuits.

In another aspect of the invention, the memory storing instructions that, when executed by the processor, cause the processor to: compare the percentage error magnitude for each forward directional coupler circuit to a predetermined percent difference threshold on an individual basis, wherein the forward directional coupler circuit is considered to be out of calibration, when the percentage error magnitude is greater than a predetermined percent difference threshold.

In another aspect of the invention, the memory storing instructions that, when executed by the processor, cause the processor to: exclude from the aggregate average forward power measurements, the individual measurements of the out of calibration directional coupler circuits.

In another aspect of the invention, the RF power sensor is considered to be out of calibration, when a number of forward coupler circuits considered to be out of calibration is greater than a predetermined out of calibration forward circuit threshold, the memory storing instructions that, when executed by the processor, cause the processor to inform a user when the RF power sensor is out of calibration.

In another aspect of the invention, the memory storing instructions that, when executed by the processor, cause the processor to: calculate a trend of the percentage error magnitudes over time to estimate a time until calibration of the RF power sensor is needed; and inform a user of the estimate of the time until calibration of the RF power sensor is needed.

In another aspect of the invention, the memory storing instructions that, when executed by the processor, cause the processor to: apply at least one environmental correction to each of the individual measurements of the at least three forward directional couplers circuits.

In another aspect of the invention, the environmental corrections correct for one or more of temperature, humidity, frequency, voltage standing waves, and/or a center conductor position error of the transmission line.

In another aspect of the invention, the memory storing instructions that, when executed by the processor, cause the processor to: calculate the correction for the temperature using a temperature sensor of the RF power sensor and a temperature characterization curve; calculate the correction for the humidity using a humidity sensor of the RF power sensor and a humidity characterization curve; calculate the correction for frequency using a non-directional coupler of the RF power sensor, a prescaler of the RF power sensor, and a frequency characterization curve; calculate the correction for the voltage standing waves using a spatial position of a forward coupler of each the forward directional coupler circuits, the measurements of the forward directional coupler circuits, a spatial position and a measurement of a reflected directional coupler of the RF power sensor, and a measurement of the reflected directional coupler; and calculate the center conductor position error correction using a spatial position longitudinally along the transmission line and rotationally around the transmission line for each of the forward couplers of the forward directional coupler circuits, and the measurements of the forward directional coupler circuits.

In another aspect of the invention, the RF power sensor is further comprised of a real-time clock, the memory storing instructions that, when executed by the processor, cause the processor to: determine if a predetermined recommended calibration time interval has elapsed since a last calibration using the real-time clock.

According to yet another aspect of the invention, a radio frequency (RF) power sensor configured to estimate a time until calibration of the RF power sensor is needed by calculating a trend of percentage error magnitudes of multiple measurements of power on a transmission line taken by at least one coupler of the power sensor over time and cross-correlation.

In another aspect of the invention, the RF power sensor has a measurement uncertainty of less than about ±0.3% achieved using the cross-correlation.

In another aspect of the invention, the power sensor is a thru-line power sensor configured to measure an RF power level greater than or equal to about 1 watt.

In another aspect of the invention, the at least one coupler is at least one forward directional coupler circuit for measuring power on the transmission line using cross-correlation for reduction of uncertainty.

In another aspect of the invention, the RF power sensor is comprised of at least three forward directional coupler circuits for measuring power on the transmission line using cross-correlation for reduction of uncertainty, wherein individual measurements of the at least three forward directional couplers circuits are averaged together, thereby producing an aggregate average forward power measurement and providing to a user as a forward power measurement of the RF power sensor.

In another aspect of the invention, the RF power sensor calculates a percentage error magnitude for each of the at least three forward directional coupler circuits using the aggregate average forward power measurement and the individual measurements of the at least three forward directional coupler circuits.

In another aspect of the invention, the percentage error magnitude for each forward directional coupler circuit is compared to a predetermined percent difference threshold on an individual basis, wherein the forward directional coupler circuit is considered to be out of calibration, when the percentage error magnitude is greater than a predetermined percent difference threshold.

In another aspect of the invention, individual measurements from the out of calibration directional coupler circuits are excluded from the aggregate average forward power measurements.

In another aspect of the invention, the RF power sensor is considered to be out of calibration, when a number of forward coupler circuits considered to be out of calibration is greater than a predetermined out of calibration forward circuit threshold, and the RF power sensor informs a user when the RF power sensor is out of calibration.

In another aspect of the invention, at least one environmental correction is applied to each of the individual measurements of the at least three forward directional couplers circuits.

In another aspect of the invention, the environmental corrections correct for one or more of temperature, humidity, frequency, voltage standing waves, and/or a center conductor position error of the transmission line.

In another aspect of the invention, the correction for the temperature is determined using a temperature sensor of the RF power sensor and a temperature characterization curve; the correction for the humidity is determined using a humidity sensor of the RF power sensor and a humidity characterization curve; the correction for frequency is determined using a non-directional coupler of the RF power sensor, a prescaler of the RF power sensor, and a frequency characterization curve; the correction for the voltage standing waves is determined using a spatial position of a forward coupler of each the forward directional coupler circuits, the measurements of the forward directional coupler circuits, a spatial position and a measurement of a reflected directional coupler of the RF power sensor, and a measurement of the reflected directional coupler; and the center conductor position error correction can be determined using a spatial position longitudinally along the transmission line and/or rotationally around the transmission line for each of the forward couplers of the forward directional coupler circuits, and the measurements of the forward directional coupler circuits.

In another aspect of the invention, the RF power sensor further comprising a real-time clock, wherein the RF power sensor uses the real-time clock to determine if a predetermined recommended calibration time interval has elapsed since a last calibration.

According to yet another aspect of the invention, a method for making an RF power measurement (operating an RF power sensor) comprising: providing an RF power sensor, and estimating a time until calibration of the RF power sensor is needed by calculating a trend of percentage error magnitudes of multiple measurements of power on a transmission line taken by at least one coupler of the power sensor over time and cross-correlation.

In another aspect of the invention, the power sensor has a measurement uncertainty of less than about ±0.3% achieved using the cross-correlation.

In another aspect of the invention, the power sensor is a thru-line power sensor configured to measure an RF power level greater than or equal to about 1 watt.

In another aspect of the invention, the at least one coupler is at least one forward directional coupler circuit for measuring power on the transmission line using cross-correlation for reduction of uncertainty.

In another aspect of the invention, the RF power sensor is comprised of at least three forward directional coupler circuits for measuring power on the transmission line using cross-correlation for reduction of uncertainty. The method further comprises: obtaining individual measurements of the at least three forward directional coupler circuits and averaging the individual measurements, thereby producing an aggregate average forward power measurement; and providing the aggregate average forward power measurement to a user as a forward power measurement of the RF power sensor.

In another aspect of the invention, the method further includes: calculating a percentage error magnitude for each of the at least three forward directional coupler circuits using the aggregate average forward power measurement and the individual measurements of the at least three forward directional coupler circuits.

In another aspect of the invention, the method further includes, comparing the percentage error magnitude for each forward directional coupler circuit to a predetermined percent difference threshold on an individual basis. The forward directional coupler circuit is considered to be out of calibration, when the percentage error magnitude is greater than a predetermined percent difference threshold.

In another aspect of the invention, the method further includes excluding from the aggregate average forward power measurements. The individual measurements of the out of calibration directional coupler circuits.

In another aspect of the invention, the RF power sensor is considered to be out of calibration, when a number of forward coupler circuits considered to be out of calibration is greater than a predetermined out of calibration forward circuit threshold, and the method further includes informing a user when the RF power sensor is out of calibration.

In another aspect of the invention, the method further includes informing a user of the estimate of the time until calibration of the RF power sensor is needed.

In another aspect of the invention, the method also includes applying at least one environmental correction to each of the individual measurements of the at least three forward directional couplers circuits.

In another aspect of the invention, the environmental corrections correct for one or more of temperature, humidity, frequency, voltage standing waves, and/or a center conductor position error of the transmission line.

In another aspect of the invention, the method further includes: the correction for the temperature is calculated using a temperature sensor of the RF power sensor and a temperature characterization curve; the correction for the humidity is calculated using a humidity sensor of the RF power sensor and a humidity characterization curve; the correction for frequency is calculated using a non-directional coupler of the RF power sensor, a prescaler of the RF power sensor, and a frequency characterization curve; the correction for the voltage standing waves is calculated using a spatial position of a forward coupler of each the forward directional coupler circuits, the measurements of the forward directional coupler circuits, a spatial position and a measurement of a reflected directional coupler of the RF power sensor, and a measurement of the reflected directional coupler; and the center conductor position error correction is calculated using a spatial position longitudinally along the transmission line and/or rotationally around the transmission line for each of the forward couplers of the forward directional coupler circuits, and the measurements of the forward directional coupler circuits.

In another aspect of the invention, the RF power sensor is further comprised of a real-time clock, the method further comprising using the real-time clock to determine if a predetermined recommended calibration time interval has elapsed since a last calibration.

In another aspect of the invention, an RF power sensor, comprising: a processor; a memory communicatively connected to the processor, the memory storing instructions that, when executed by the processor, cause the processor to: estimate a time until calibration of the RF power sensor is needed by calculating a trend of percentage error magnitudes of multiple measurements of power on a transmission line taken by at least one coupler of the power sensor over time and cross-correlation.

In another aspect of the invention, the power sensor has a measurement uncertainty of less than about ±0.3% achieved using the cross-correlation.

In another aspect of the invention, the power sensor is a thru-line power sensor configured to measure an RF power level greater than or equal to about 1 watt.

In another aspect of the invention, the at least one coupler is at least one forward directional coupler circuit for measuring power on the transmission line using cross-correlation for reduction of uncertainty.

In another aspect of the invention, the RF power sensor is comprised of at least three forward directional coupler circuits. The memory storing instructions that, when executed by the processor, cause the processor to: measure power on the transmission line using cross-correlation for reduction of uncertainty; calculate an aggregate average forward power measurement using individual measurements of the at least three forward directional couplers circuits; and provide the aggregate average forward power measurement to a user as a forward power measurement of the RF power sensor.

In another aspect of the invention, the memory storing instructions that, when executed by the processor, cause the processor to calculate a percentage error magnitude for each of the at least three forward directional coupler circuits using the aggregate average forward power measurement and the individual measurements of the at least three forward directional coupler circuits.

In another aspect of the invention, the memory storing instructions that, when executed by the processor, cause the processor to compare the percentage error magnitude for each forward directional coupler circuit to a predetermined percent difference threshold on an individual basis, wherein the forward directional coupler circuit is considered to be out of calibration, when the percentage error magnitude is greater than a predetermined percent difference threshold.

In another aspect of the invention, the memory storing instructions that, when executed by the processor, cause the processor to exclude from the aggregate average forward power measurements, the individual measurements of the out of calibration directional coupler circuits.

In another aspect of the invention, the RF power sensor is considered to be out of calibration, when a number of forward coupler circuits considered to be out of calibration is greater than a predetermined out of calibration forward circuit threshold. The memory storing instructions that, when executed by the processor, cause the processor to inform a user when the RF power sensor is out of calibration.

In another aspect of the invention, the memory storing instructions that, when executed by the processor, cause the processor to inform a user of the estimate of the time until calibration of the RF power sensor is needed.

In another aspect of the invention, the memory storing instructions that, when executed by the processor, cause the processor to apply at least one environmental correction to each of the individual measurements of the at least three forward directional couplers circuits.

In another aspect of the invention, the environmental corrections correct for one or more of temperature, humidity, frequency, voltage standing waves, and/or a center conductor position error of the transmission line.

In another aspect of the invention, the memory storing instructions that, when executed by the processor, cause the processor to: calculate the correction for the temperature using a temperature sensor of the RF power sensor and a temperature characterization curve; calculate the correction for the humidity using a humidity sensor of the RF power sensor and a humidity characterization curve; calculate the correction for frequency using a non-directional coupler of the RF power sensor, a prescaler of the RF power sensor, and a frequency characterization curve; calculate the correction for the voltage standing waves using a spatial position of a forward coupler of each the forward directional coupler circuits, the measurements of the forward directional coupler circuits, a spatial position and a measurement of a reflected directional coupler of the RF power sensor, and a measurement of the reflected directional coupler; and calculate the center conductor position error correction using a spatial position longitudinally along the transmission line and rotationally around the transmission line for each of the forward couplers of the forward directional coupler circuits, and the measurements of the forward directional coupler circuits.

In another aspect of the invention, the RF power sensor is further comprised of a real-time clock, the memory storing instructions that, when executed by the processor, cause the processor to determine if a predetermined recommended calibration time interval has elapsed since a last calibration using the real-time clock.

According to yet another aspect of the invention, a radio frequency (RF) power sensor comprises a real-time clock. The RF power sensor uses the real-time clock to determine if a predetermined recommended calibration time interval has elapsed since a last calibration, and the power sensor informs the user when the predetermined recommended calibration time interval has elapsed.

In another aspect of the invention, the power sensor has a measurement uncertainty of less than about ±0.3%. The measurement uncertainty of less than about ±0.3% is achieved using cross-correlation. The power sensor is a thru-line power sensor configured to measure an RF power level greater than or equal to about 1 watt.

In another aspect of the invention, the RF power sensor is comprised of a transmission line and at least one forward directional coupler circuit for measuring power on the transmission line using cross-correlation for reduction of uncertainty.

In another aspect of the invention, the RF power sensor is comprised of at least three forward directional coupler circuits for measuring power on the transmission line using cross-correlation for reduction of uncertainty. Individual measurements of the at least three forward directional couplers circuits are averaged together, thereby producing an aggregate average forward power measurement and providing to a user as a forward power measurement of the RF power sensor.

In another aspect of the invention, the RF power sensor calculates a percentage error magnitude for each of the at least three forward directional coupler circuits using the aggregate average forward power measurement and the individual measurements of the at least three forward directional coupler circuits.

In another aspect of the invention, the percentage error magnitude for each forward directional coupler circuit is compared to a predetermined percent difference threshold on an individual basis. The forward directional coupler circuit is considered to be out of calibration, when the percentage error magnitude is greater than a predetermined percent difference threshold.

In another aspect of the invention, individual measurements from the out of calibration directional coupler circuits are excluded from the aggregate average forward power measurements.

In another aspect of the invention, the RF power sensor is considered to be out of calibration, when a number of forward coupler circuits considered to be out of calibration is greater than a predetermined out of calibration forward circuit threshold. The RF power sensor informs a user when the RF power sensor is out of calibration.

In another aspect of the invention, the RF power sensor calculates a trend of the percentage error magnitudes over time to estimate a time until calibration of the RF power sensor is needed.

In another aspect of the invention, at least one environmental correction is applied to each of the individual measurements of the at least three forward directional couplers circuits.

In another aspect of the invention, the environmental corrections correct for one or more of temperature, humidity, frequency, voltage standing waves, and/or a center conductor position error of the transmission line.

In another aspect of the invention, the correction for the temperature is determined using a temperature sensor of the RF power sensor and a temperature characterization curve; the correction for the humidity is determined using a humidity sensor of the RF power sensor and a humidity characterization curve; the correction for frequency is determined using a non-directional coupler of the RF power sensor, a prescaler of the RF power sensor, and a frequency characterization curve; the correction for the voltage standing waves is determined using a spatial position of a forward coupler of each the forward directional coupler circuits, the measurements of the forward directional coupler circuits, a spatial position and a measurement of a reflected directional coupler of the RF power sensor, and a measurement of the reflected directional coupler; and the center conductor position error correction is determined using a spatial position longitudinally along the transmission line and/or rotationally around the transmission line for each of the forward couplers of the forward directional coupler circuits, and the measurements of the forward directional coupler circuits.

According to yet another aspect of the invention, a method for making a radio frequency (RF) power measurement (operating an RF power sensor) comprising: providing an RF power sensor having a real-time clock; determining if a predetermined recommended calibration time interval has elapsed since a last calibration, using the real time clock; and informing a user when the predetermined recommended calibration time interval has elapsed.

In another aspect of the invention, the power sensor has a measurement uncertainty of less than about ±0.3% and cross-correlation is used to achieve the uncertainty of less than about ±0.3%.

In another aspect of the invention, the RF power sensor is comprised of a transmission line and at least one forward directional coupler circuit for measuring power on the transmission line using cross-correlation for reduction of uncertainty.

In another aspect of the invention, the RF power sensor is comprised of at least three forward directional coupler circuits for measuring power on the transmission line using cross-correlation for reduction of uncertainty. The method further comprises: obtaining individual measurements of the at least three forward directional coupler circuits and averaging the individual measurements, thereby producing an aggregate average forward power measurement; and providing the aggregate average forward power measurement to a user as a forward power measurement of the RF power sensor.

In another aspect of the invention, the method further includes calculating a percentage error magnitude for each of the at least three forward directional coupler circuits using the aggregate average forward power measurement and the individual measurements of the at least three forward directional coupler circuits.

In another aspect of the invention, the method further includes comparing the percentage error magnitude for each forward directional coupler circuit to a predetermined percent difference threshold on an individual basis. The forward directional coupler circuit is considered to be out of calibration, when the percentage error magnitude is greater than a predetermined percent difference threshold.

In another aspect of the invention, the method further comprises excluding from the aggregate average forward power measurements, the individual measurements of the out of calibration directional coupler circuits.

In another aspect of the invention, the RF power sensor is considered to be out of calibration, when a number of forward coupler circuits considered to be out of calibration is greater than a predetermined out of calibration forward circuit threshold. The method further includes informing a user when the RF power sensor is out of calibration.

In another aspect of the invention, the method further includes calculating a trend of the percentage error magnitudes over time to estimate a time until calibration of the RF power sensor is needed, and informing a user of the estimate of the time until calibration of the RF power sensor is needed.

In another aspect of the invention, the method further includes applying at least one environmental correction to each of the individual measurements of the at least three forward directional couplers circuits.

In another aspect of the invention, the environmental corrections correct for one or more of temperature, humidity, frequency, voltage standing waves, and/or a center conductor position error of the transmission line.

In another aspect of the invention, the correction for the temperature is calculated using a temperature sensor of the RF power sensor and a temperature characterization curve; the correction for the humidity is calculated using a humidity sensor of the RF power sensor and a humidity characterization curve; the correction for frequency is calculated using a non-directional coupler of the RF power sensor, a prescaler of the RF power sensor, and a frequency characterization curve; the correction for the voltage standing waves is calculated using a spatial position of a forward coupler of each the forward directional coupler circuits, the measurements of the forward directional coupler circuits, a spatial position and a measurement of a reflected directional coupler of the RF power sensor, and a measurement of the reflected directional coupler; and the center conductor position error correction is calculated using a spatial position longitudinally along the transmission line and/or rotationally around the transmission line for each of the forward couplers of the forward directional coupler circuits, and the measurements of the forward directional coupler circuits.

According to yet another aspect of the invention, an RF power sensor includes: a real time clock; a processor; and memory communicatively connected to the processor, the memory storing instructions that, when executed by the processor, cause the processor to: determine if a predetermined recommended calibration time interval has elapsed since a last calibration, using the real time clock, and inform a user when the predetermined recommended calibration time interval has elapsed.

In another aspect of the invention, the power sensor is configured to measure an RF power level greater than or equal to about 1 watt, the power sensor has a measurement uncertainty of less than about ±0.3% using cross-correlation, the power sensor is a thru-line power sensor.

In another aspect of the invention, the RF power sensor has a transmission line and at least one forward directional coupler circuit for measuring power on the transmission line using cross-correlation for reduction of uncertainty.

In another aspect of the invention, the RF power sensor is comprised of at least three forward directional coupler circuits, the memory storing instructions that, when executed by the processor, cause the processor to: measure power on the transmission line using cross-correlation for reduction of uncertainty; calculate an aggregate average forward power measurement using individual measurements of the at least three forward directional couplers circuits; and provide the aggregate average forward power measurement to a user as a forward power measurement of the RF power sensor.

In another aspect of the invention, the memory storing instructions that, when executed by the processor, cause the processor to: calculate a percentage error magnitude for each of the at least three forward directional coupler circuits using the aggregate average forward power measurement and the individual measurements of the at least three forward directional coupler circuits.

In another aspect of the invention, the forward directional coupler circuit is considered to be out of calibration, when the percentage error magnitude is greater than a predetermined percent difference threshold. The memory storing instructions that, when executed by the processor, cause the processor to compare the percentage error magnitude for each forward directional coupler circuit to a predetermined percent difference threshold on an individual basis.

In another aspect of the invention, the memory storing instructions that, when executed by the processor, cause the processor to exclude from the aggregate average forward power measurements, the individual measurements of the out of calibration directional coupler circuits.

In another aspect of the invention, the RF power sensor is considered to be out of calibration, when a number of forward coupler circuits considered to be out of calibration is greater than a predetermined out of calibration forward circuit threshold. The memory storing instructions that, when executed by the processor, cause the processor to inform a user when the RF power sensor is out of calibration.

In another aspect of the invention, the memory storing instructions that, when executed by the processor, cause the processor to calculate a trend of the percentage error magnitudes over time to estimate a time until calibration of the RF power sensor is needed; and inform a user of the estimate of the time until calibration of the RF power sensor is needed.

In another aspect of the invention, the memory storing instructions that, when executed by the processor, cause the processor to apply at least one environmental correction to each of the individual measurements of the at least three forward directional couplers circuits.

In another aspect of the invention, the environmental corrections correct for one or more of temperature, humidity, frequency, voltage standing waves, and/or a center conductor position error of the transmission line.

In another aspect of the invention, the memory storing instructions that, when executed by the processor, cause the processor to: calculate the correction for the temperature using a temperature sensor of the RF power sensor and a temperature characterization curve; calculate the correction for the humidity using a humidity sensor of the RF power sensor and a humidity characterization curve; calculate the correction for frequency using a non-directional coupler of the RF power sensor, a prescaler of the RF power sensor, and a frequency characterization curve; calculate the correction for the voltage standing waves using a spatial position of a forward coupler of each the forward directional coupler circuits, the measurements of the forward directional coupler circuits, a spatial position and a measurement of a reflected directional coupler of the RF power sensor, and a measurement of the reflected directional coupler; and calculate the center conductor position error correction using a spatial position longitudinally along the transmission line and/or rotationally around the transmission line for each of the forward couplers of the forward directional coupler circuits, and the measurements of the forward directional coupler circuits.

Advantages of the present invention will become more apparent to those skilled in the art from the following description of the embodiments of the invention which have been shown and described by way of illustration. As will be realized, the invention is capable of other and different embodiments, and its details are capable of modification in various respects.

### BRIEF DESCRIPTION OF THE DRAWINGS

FIG. 1 is an exploded view of a radio frequency (RF) power sensor in accordance with an exemplary embodiment of the invention;

FIG. 2 is a top plan view of the RF power sensor in accordance with an exemplary embodiment of the invention of FIG. 1;

FIG. 3 is a block diagram illustrating the arrangement of the electrical components used in the RF power sensor in accordance with an exemplary embodiment of the invention of FIGS. 1 and 2;

FIG. 4 is view down the longitudinal axis of the transmission line of an RF power sensor in accordance with an exemplary embodiment of the invention of FIGS. 1-3; and

FIG. 5 is a method of using the RF power sensor in accordance with an exemplary embodiment of the invention of FIGS. 1-4.

It should be noted that all the drawings are diagrammatic and not drawn to scale. Relative dimensions and proportions of parts of these figures have been shown exaggerated or reduced in size for the sake of clarity and convenience in the drawings. The same reference numbers are generally used to refer to corresponding or similar features in the different embodiments. Accordingly, the drawing(s) and description are to be regarded as illustrative in nature and not as restrictive.

### DETAILED DESCRIPTION OF THE INVENTION

Approximating language, as used herein throughout the specification and claims, may be applied to modify any quantitative representation that could permissibly vary without resulting in a change in the basic function to which it is related. Accordingly, a value modified by a term or terms, such as “about”, is not limited to the precise value specified. In at least some instances, the approximating language may correspond to the precision of an instrument for measuring the value. Range limitations may be combined and/or interchanged, and such ranges are identified and include all the sub-ranges stated herein unless context or language indicates otherwise. Other than in the operating examples or where otherwise indicated, all numbers or expressions referring to quantities of ingredients, reaction conditions and the like, used in the specification and the claims, are to be understood as modified in all instances by the term “about”.

“Optional” or “optionally” means that the subsequently described event or circumstance may or may not occur, or that the subsequently identified material may or may not be present, and that the description includes instances where the event or circumstance occurs or where the material is present, and instances where the event or circumstance does not occur or the material is not present.

As used herein, the terms “comprises”, “comprising”, “includes”, “including”, “has”, “having”, or any other variation thereof, are intended to cover a non-exclusive inclusion. For example, a process, method, article or apparatus that comprises a list of elements is not necessarily limited to only those elements, but may include other elements not expressly listed or inherent to such process, method, article, or apparatus.

The singular forms “a”, “an”, and “the” include plural referents unless the context clearly dictates otherwise.

A “processor”, as used herein, processes signals and performs general computing and arithmetic functions. Signals processed by the processor can include digital signals, data signals, computer instructions, processor instructions, messages, a bit, a bit stream, or other means that can be received, transmitted and/or detected. Generally, the processor can be a variety of various processors including multiple single and multicore processors and co-processors and other multiple single and multicore processor and co-processor architectures, including, but not limited to, a microcontroller containing both a processor and memory, programmable logic array (PLA), application specific integrated circuit (ASIC), or any type of device suitable for processing signals, performing general computing, and/or arithmetic functions. The processor can include various modules to execute various functions.

A “memory”, as used herein can include volatile memory and/or nonvolatile memory. Non-volatile memory can include, for example, ROM (read only memory), PROM (programmable read only memory), EPROM (erasable PROM), and EEPROM (electrically erasable PROM). Volatile memory can include, for example, RAM (random access memory), synchronous RAM (SRAM), dynamic RAM (DRAM), synchronous DRAM (SDRAM), double data rate SDRAM (DDRSDRAM), and direct RAM bus RAM (DRRAM). The memory can also include a disk. The memory can store an operating system that controls or allocates resources of a computing device. The memory can also store data for use by the processor.

A “module”, as used herein, includes, but is not limited to, hardware, firmware, software in execution on a machine, and/or combinations of each to perform a function(s) or an action(s), and/or to cause a function or action from another module, method, and/or system. A module can include a software controlled microprocessor, a discrete logic circuit, an analog circuit, a digital circuit, a programmed logic device, a memory device containing executing instructions, and so on.

A “disk”, as used herein can be, for example, a magnetic disk drive, a solid state disk drive, a floppy disk drive, a tape drive, a Zip drive, a flash memory card, and/or a memory stick. Furthermore, the disk can be a CD-ROM (compact disk ROM), a CD recordable drive (CD-R drive), a CD rewritable drive (CD-RW drive), and/or a digital video ROM drive (DVD ROM). The disk can store an operating system and/or program that controls or allocates resources of a computing device.

Some portions of the detailed description that follows are presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of steps (instructions) leading to a desired result. The steps are those requiring physical manipulations of physical quantities. Usually, though not necessarily, these quantities take the form of electrical, magnetic or optical non-transitory signals capable of being stored, transferred, combined, compared and otherwise manipulated. It is convenient at times, principally for reasons of common usage, to refer to these signals as bits, values, elements, symbols, characters, terms, numbers, or the like. Furthermore, it is also convenient at times, to refer to certain arrangements of steps requiring physical manipulations or transformation of physical quantities or representations of physical quantities as modules or code devices, without loss of generality.

However, all of these and similar terms are to be associated with the appropriate physical quantities and are merely convenient labels applied to these quantities. Unless specifically stated otherwise as apparent from the following discussion, it is appreciated that throughout the description, discussions utilizing terms such as “processing” or “computing” or “calculating” or “determining” or “displaying” or “determining” or the like, refer to the action and processes of a computer system, or similar electronic computing device (such as a specific computing machine), that manipulates and transforms data represented as physical (electronic) quantities within the computer system memories or registers or other such information storage, transmission or display devices.

Certain aspects of the embodiments described herein include process steps and instructions described herein in the form of an algorithm. It should be noted that the process steps and instructions of the embodiments could be embodied in software, firmware or hardware, and when embodied in software, could be downloaded to reside on and be operated from different platforms used by a variety of operating systems. The embodiments can also be in a computer program product which can be executed on a computing system.

The embodiments also relates to an apparatus for performing the operations herein. This apparatus can be specially constructed for the purposes, e.g., a specific computer, or it can comprise a general-purpose computer selectively activated or reconfigured by a computer program stored in the computer. Such a computer program can be stored in a non-transitory computer readable storage medium, such as, but is not limited to, any type of disk including floppy disks, optical disks, CD-ROMs, magnetic-optical disks, read-only memories (ROMs), random access memories (RAMs), EPROMS, EEPROMs, magnetic or optical cards, ASICs, or any type of media suitable for storing electronic instructions, and each electrically connected to a computer system bus. Furthermore, the computers referred to in the specification can include a single processor or can be architectures employing multiple processor designs for increased computing capability.

The algorithms and displays presented herein are not inherently related to any particular computer or other apparatus. Various general-purpose systems can also be used with programs in accordance with the teachings herein, or it can prove convenient to construct more specialized apparatus to perform the method steps. The structure for a variety of these systems will appear from the description below. In addition, the embodiments are not described with reference to any particular programming language. It will be appreciated that a variety of programming languages can be used to implement the teachings of the embodiments as described herein, and any references below to specific languages are provided for disclosure of enablement and best mode of the embodiments.

In addition, the language used in the specification has been principally selected for readability and instructional purposes, and may not have been selected to delineate or circumscribe the inventive subject matter. Accordingly, the disclosure of the embodiments is intended to be illustrative, but not limiting, of the scope of the embodiments, which is set forth in the claims.

The present state of the art in-line RF power measurement accuracy is around ±0.5%. This limitation is due to the combination of a variety of sources of uncertainty, including, but not limited to, the calibration standard, temperature, humidity, mechanical stability, frequency response, dynamic non-linearities, noise, connector wear, and aging. Some of these uncertainties are consistent throughout the life of the sensor, but others change with time, causing the sensor accuracy to exceed its specified limits. This is one of the main reasons for the regular recalibration of RF power sensors, often every 6 or 12 months.

Calibration approaches for currently available in-line RF power sensors call for the removal of the power sensor from the RF power delivery path so that it may be returned to the factory for calibration. The major issue associated with this process is that the RF system must be shut down while the in-line power sensor is removed from the system and temporarily replaced with either a spare power sensor or a temporary transmission line section. Furthermore, the removal and replacement of the power sensor with a spare power sensor opens the door for process shifts due to the difference in power measurement between the two sensors. Due to the inherent inconvenience, opportunity for process shifts, and loss of revenue associated with an RF system shut down and equipment removal, most power sensors are either calibrated very infrequently or not calibrated altogether. This inconvenience is also present for RF power sensors that are not installed in an RF system, but used in a calibration or verification context, where RF power is only used when the calibration or verification if performed.

Calibration date and the next recommended calibration date are typically marked on the power sensor by means of a physical calibration label and/or indicated on the documents that accompany a sensor calibration. Sometimes this information may also be stored in power sensor memory, but given that power sensors in the semiconductor market are typically used as standalone devices without any network access, they have no knowledge of the current calendar date. As such, the sensor itself has no way of knowing whether it is approaching or has passed the next recommended calibration date and can give no warning to the user. This information must be tracked externally by the user and/or their metrology group, running the risk that a power sensor is unknowingly out of calibration.

In view of these limitations, a need exists for a RF power sensor that can achieve a power measurement accuracy of better than ±0.5%, maintain that accuracy over time, reduce the need for frequent recalibration, and inform the user whether recalibration is required if an out-of-calibration condition is detected.

The present invention satisfies the needs described above and affords other features and advantages heretofore not obtainable. Referring more particularly to the drawings, there is shown an embodiment of the invention, self-monitoring high accuracy radio frequency power sensor.

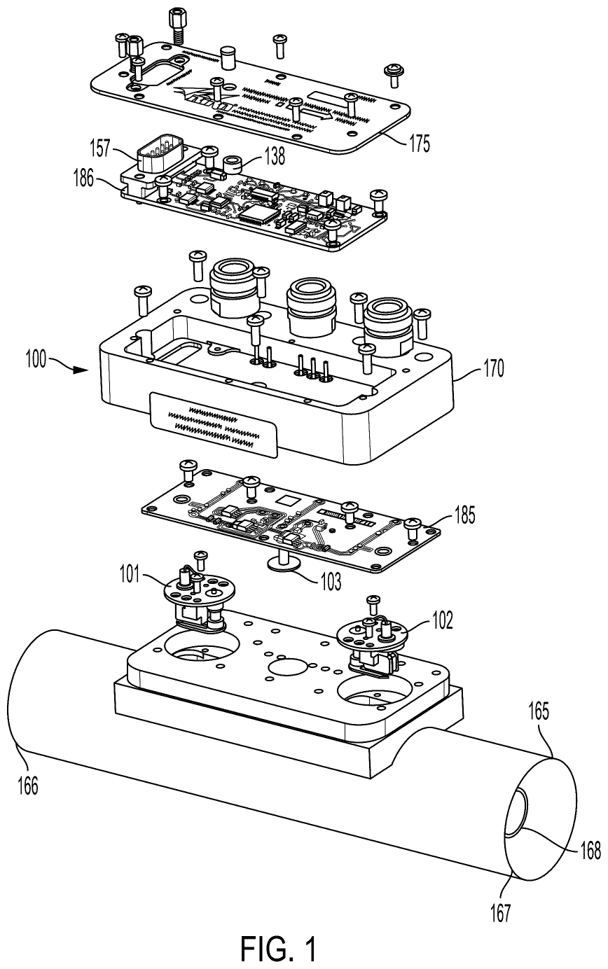

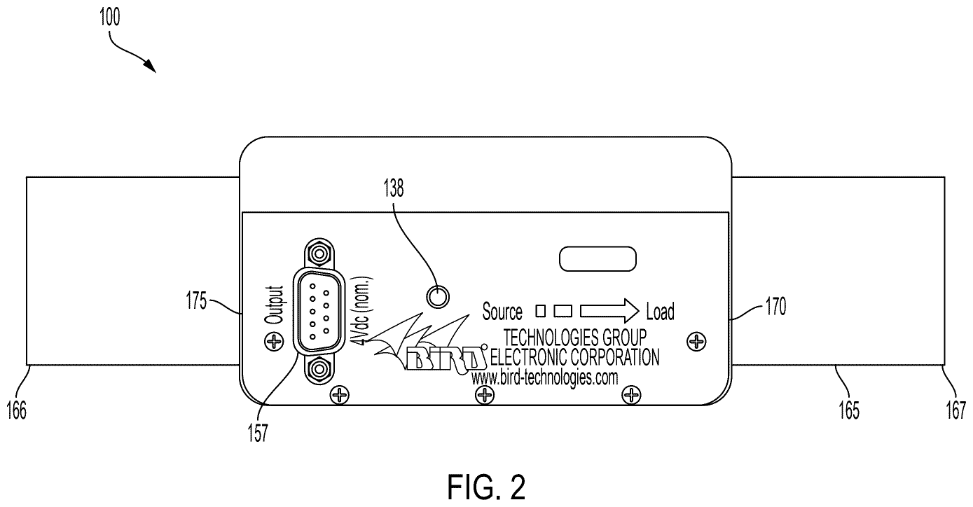

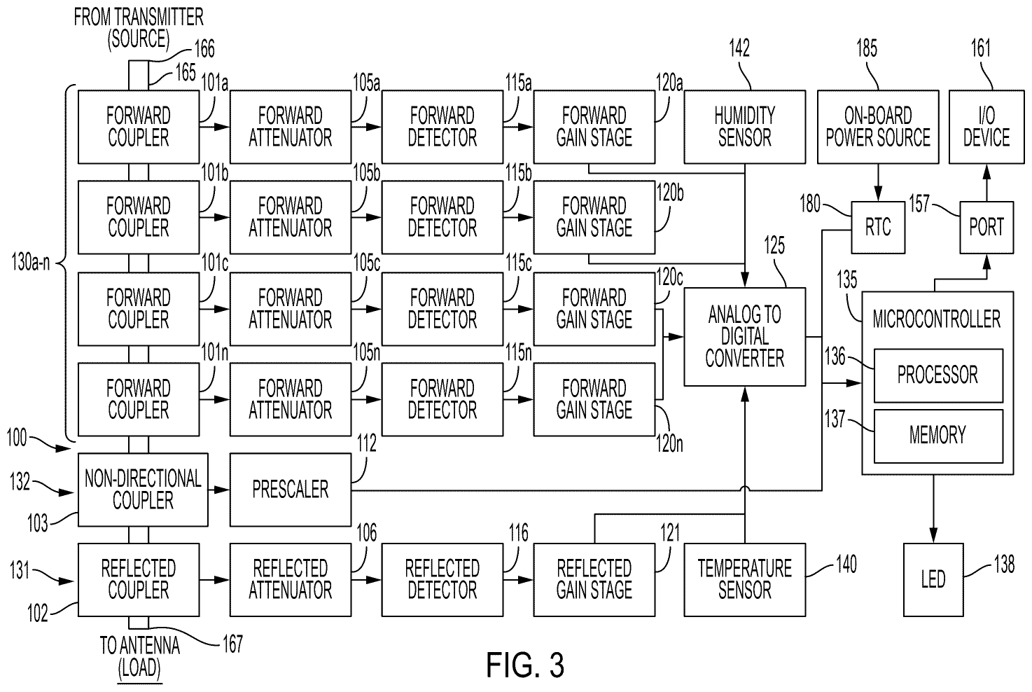

Referring to FIGS. 1-3, a self-monitoring high accuracy radio frequency (RF) power sensor 100 a measurement uncertainty of less than about ±0.3%. In an exemplary embodiment, power sensor 100 may be a thru-line power sensor. Further, in exemplary embodiments, power sensor 100 may be capable of measuring an RF power level greater than or equal to about 1 watt (power handling capability of greater than or equal to about 1 watt). Power sensor 100 comprises a transmission line section 165 having a body 170 is fastened to the transmission line section 165. Forward directional couplers 101a-n, reflected directional coupler 102, and non-directional coupler 103 are located inside the body 170. In some exemplary embodiments, the body 170 may be rectangular and may have a cover 175. In some exemplary embodiments, body 170 may be a shape other than rectangular and may be dictated by the positioning of the couplers contained therein along the transmission line 165. In an exemplary embodiment, non-directional coupler 103 is mounted on a RF board 185, while the RF board 185 is placed on top of forward and reflected couplers 101a-n and 102. All of the couplers 101a-n, 102, and 103 interface with the RF board. Some exemplary embodiments of power sensor 100 may have three forward couplers 101a-c. However, it is contemplated that other exemplary embodiments of power sensor 100 may have more or less forward couplers 101a-n, with “n” being the letter in the alphabet equivalent to the number of forward couplers present.

A logic board 186 is placed on top of and interfaces with the RF board 185. The logic board 186 has a port 157 and LED 138. The port 157 may be a USB port, Ethernet port, or any other suitable port for communicating with the logic board 186 of power sensor 100. The port 157 is accessible through the cover 175 and LED 138 is visible through the cover 175. The port 157 provides an output of the various measurements of power sensor 100 to a user via I/O device 161. I/O device 161 can include, but is not limited to, a screen, computer, mobile device, or a server. I/O device 161 can be hardwired to port 157 or wirelessly connected to port 157, such as, but not limited to, WiFi or Bluetooth, or communicate via a combination of wireless and wired networks.

In some exemplary embodiments, power sensor 100 comprises a transmission line section 165 with a source end 166 and a load end 167. A body 170 is fastened to the transmission line 165. The body 170 can have a cover 175. A port 157 is accessible through the cover 175 and an LED 138 is visible through the cover 175.

In operation, radio frequency (RF) voltage samples of the transmission line power are made available by the forward directional coupler 101a-c and reflected directional coupler 102. A non-directional voltage coupler 103 is used by the microcontroller 135 to measure the RF frequency of the RF signal. In some exemplary embodiments, the couplers 101a-c and 102 may be part number 7006A216 from Bird Technologies Group. The samples of the main transmission line power provided by the forward couplers 101a-c and reflected coupler 102 are approximately −55 dB from the main transmission line power. The transmission line 165 has a source end 166 and a load end 167.

The prescaler 112 measures the frequency of the sample of the main transmission line power provided by the non-directional coupler 103 and divides the frequency down to a digital representation of a lower frequency that can be measured by the microcontroller 135. The output of the prescaler 112 is provided to the microcontroller 135. In other exemplary embodiments, the prescaler 112 outputs an analog signal to the analog to digital converter 125. The non-directional coupler 103 and prescaler, 112 form the non-directional circuit 132.

The RF voltage samples from the forward directional couplers 101a-c are routed to the forward power attenuators 105a-c respectively, while RF voltage samples from the reflected directional coupler 102 are routed to the reflected power attenuator 106. The number of forward power attenuators 105a-n correspond with the number of forward couplers 101a-n present in the power sensor 100, with “n” being the letter in the alphabet equivalent to the number of forward couplers present. The forward power attenuators 105a-c and reflected power attenuator 106 are resistive attenuators for setting the appropriate voltage levels for the forward detectors 115a-c and reflected detector 116. In an exemplary embodiment, the forward power attenuators 105a-c and reflected power attenuator 106 are contained in an RF circuit assembly from Bird Technologies Group.

The forward power attenuator 105a-c outputs a RF voltage to the forward detectors 115a-c respectively. The reflected power attenuator 106 outputs a RF voltage to the reflected detector 116.

The forward detectors 115a-c and reflected detector 116 use diodes to convert the RF voltages into small direct current (DC) voltages. The number of forward detectors 115a-n correspond with the number of forward couplers 101a-n present in power sensor 100, with “n” being the letter in the alphabet equivalent to the number of forward couplers 101 present.

The output of the forward detector 115a-c is amplified by a forward gain stage 120a-c respectively and the output of the reflected detector 116 is amplified by a reflected gain stage 121. The forward gain stages 120a-c and reflected gain stage 121 are precision operational amplifiers with very high input impedances to not load down the diodes. The number of forward gain stages 120a-n correspond with the number of forward couplers 101a-n present in power sensor 100, with “n” being the letter in the alphabet equivalent to the number of forward couplers 101 present.

In an exemplary embodiment, the output of the forward gain stages 120a-c and reflected gain stage 121 is approximately 2 volts DC at the full scale rating of the instrument.

The power sensor 100 may also have forward coupler circuits 130a-c. The components of the forward coupler circuits 130a-c may include, but are not limited to, forward couplers 101a-c, forward attenuators 105a-c, forward detectors 115a-c, and forward gain stages 120a-c. The number of forward coupler circuits 120a-n correspond with the number of forward couplers 101a-n present in power sensor 100, with “n” being the letter in the alphabet equivalent to the number of forward couplers 101 present.

In exemplary embodiments where an individual analog to digital converter 125 is used for each forward coupler circuit 130a-n, then the forward coupler circuits 130a-n may also include the analog to digital converters 125a-n and may provide outputs directly to microcontroller 135. In exemplary embodiments where an individual analog to digital converter 125 is not used for each forward coupler circuit 130a-n, then the outputs of the individual forward coupler circuits 130a-n may be provided to one or more analog to digital converters 125, which will then digitize the outputs of the forward coupler circuits 130a-n and provide digitized representations of the outputs to the microcontroller 135.

Forward gain stages 120a-c and reflected gain stage 121 output the amplified DC voltage to an analog to digital converter 125. The temperature sensor 140 and humidity sensor 142 also sends a signals to the analog to digital converter 125.

The analog to digital converter 125 digitizes the signals from the forward gain stage outputs 120a-c, reflected gain stage output 121, humidity sensor 142, and temperature sensor 140 and sends the digital signals to the microcontroller 135. The temperature sensor 140 and humidity sensor 142 are located in close proximity to the detectors 115a-c and 116. Components in the power sensor 100, such as, the output of detectors 115a-c and 116 and, can vary based on the ambient air temperature and relative humidity. The microcontroller 135 uses the digitized temperature sensor 140 output and digitized humidity sensor 142 output in conjunction with the temperature characterization curve and humidity characterization curve of the detectors 115a-c and 116 stored in microcontroller 135 to correct for the effects of thermally and humidity induced drift in the power sensor 100, such as, but not limited to, forward and reflected detectors 115a-c and 116.

Similarly, the uncertainty of the outputs of some power measurement components of the power sensor 100 may vary based on frequency. Therefore, the microcontroller 135 uses the output of the prescaler 112 in conjunction with an applicable frequency characterization curve stored in microcontroller 135 to correct for (reduce) the effects of frequency on the uncertainty of the power sensor 100. The power measurement components of the power sensor 100 that may vary based on frequency include, can include, but are not limited to, one or more of the components in the forward coupler circuits 130a-n, which may include, but are not limited to, forward couplers 101a-n. The power measurement components of the power sensor 100 of which uncertainty may vary based on frequency can also include, but are not limited to, any components of the non-directional coupler circuit 132, such as, but not limited to non-directional coupler 103. Further, the power measurement components of the power sensor 100 of which uncertainty may vary based on frequency may also include any component located in the signal path between a coupler and the microcontroller 135. The coupler can be one or more of forward couplers 101a-n, reflected coupler 102, and/or non-directional coupler 103.

The microcontroller 135 provides an output to the LED 138, which provides a visual indication of the calibration status. In an exemplary embodiment, the LED 138 states may be as follows: the LED 138 turns off when the power sensor 100 is within calibration; and LED 138 blinks if the power sensor 100 is in need of being calibrated (not in calibration).

The main task of the microcontroller 135 is to linearize the diode detectors output, provide some digital averaging of the data received from the analog to digital converter 125, perform temperature, humidity, and frequency correction, and keep track of the time since the previous calibration.

In an exemplary embodiment, microcontroller 135 may have a processor 136 and memory 137. The processor 136 may be used to store in memory 137 power measurements obtained from the forward couplers 101a-n of the forward coupler circuits 130a-n, power measurements obtained from the reflected coupler 102 of the reflected coupler circuit 131, frequency measurements obtained by the non-directional coupler 103 of the non-directional coupler circuit 132, temperature measurements obtained by the temperature sensor 140, and humidity measurements obtained by humidity sensor 142, such as relative humidity.

Further, in other exemplary embodiments, it is contemplated that a user can replace microcontroller 135 with suitable stand along processor 136 and memory 137, application specific integrated circuit, field programmable gate array, or discrete circuitry. It is also contemplated that the functions of the forward gain stages 120a-c and reflected gain stage 121, analog to digital converter 125 and digital to analog converter 145 can be replicated or replaced using one or more of suitable microcontroller, processor and memory, application specific integrated circuit, field programmable gate array, or discrete circuitry.

In some exemplary embodiments, the power sensor 100 may have a real-time clock (RTC) 180 that the power sensor 100 may use to determine if a predetermined recommended calibration time interval has elapsed. In an exemplary embodiment, the predetermined recommended calibration time interval may be 6 months, in other exemplary embodiments it may be 12 months. Further, it is contemplated that the predetermined recommended calibration time interval for power sensor 100 may be another time interval deemed suitable by a person having ordinary skill in the art.

In some exemplary embodiments, the RTC 180 may be used, in conjunction with processor 136 and memory 137, to keep track of the elapsed time since the previous (last) calibration and can determine if the predetermined recommended calibration time interval has elapsed. In some exemplary embodiments, the output of the RTC 180 may be provided directly to the processor 136.

In further exemplary embodiments of power sensor 100, RTC 180 may keep track of the elapsed time and may determine itself if the predetermined recommended calibration interval has elapsed. When the predetermined recommended calibration interval has elapsed, the RTC may then inform the processor 136 that the power sensor 100 is out of calibration.

In some exemplary embodiments of power sensor 100, RTC 180 may be integrated into the microcontroller 135, and in other exemplary embodiments RTC 180 may be stand-alone from the microcontroller 135.

In some exemplary embodiments of power sensor 100, RTC 180 may be powered by an on-board power source 185 (power source on-board the power sensor 100), such as, but not limited to a battery or capacitor. The on-board power source 185 may permit the power sensor 100 to keep track of the current date and time, using the RTC 180, regardless of whether the power sensor 100 is provided with external power. It is further contemplated that in some exemplary embodiments of power sensor 100, the RTC 180 and other circuitry of power sensor 100 required for informing the user of the calibration status of power sensor 100 may also be provided with power from the on-board power source 185, when external power is not available to the power sensor 100. Such additional circuitry may include, but is not limited to, one or more of microcontroller 135, processor 136, memory 137, LED 138, analog-to-digital converter 125 and/or port 157.

In some exemplary embodiments of power sensor 100, when power sensor 100 is not provided with external power, the RTC 180 and LED 138 may also be provided with power from the on-board power source 185, and the RTC 180 may be able to control the state (status) of the LED 138 independently of the processor 136, thereby permitting RTC 180 through the LED 138 to inform the user of the calibration status of power sensor 100.

Turning to FIGS. 1-4, it is also contemplated that in some exemplary embodiments, the forward couplers 101a-n of power sensor 100 may be spaced apart linearly along the transmission line 165, in other exemplary embodiments, the forward couplers 101a-n may be arranged radially around the transmission line 165, and in further exemplary embodiments, the forward couplers 101a-n may be spaced both linearly along, as well as spaced radially around the transmission line 165.

Further, the spatial placement of the forward couplers 101a-n along the transmission line 165, such as the linear placement of the forward couplers 101a-n along the transmission line 165, permit the power sensor 100 to measure and remove the uncertainty (error) associated with voltage standing waves on transmission line 165. In the presence of a mismatch, the reflected signal varies in voltage and phase along the length of the transmission line. Therefore, since measurements are taken by forward couplers 101a-n at various known points along the line of a signal having a known frequency, this information can be used by the power sensor 100 to remove any uncertainty (error) associated with the reflected signal.

Additionally, the various types of couplers, sensors, and associated circuitry present in the power sensor 100, such as, but not limited to, the forward couplers 101a-n, reflected coupler 102, non-directional coupler 103, temperature sensor 140, and humidity sensor 142, provide additional degrees of independence between measurements.

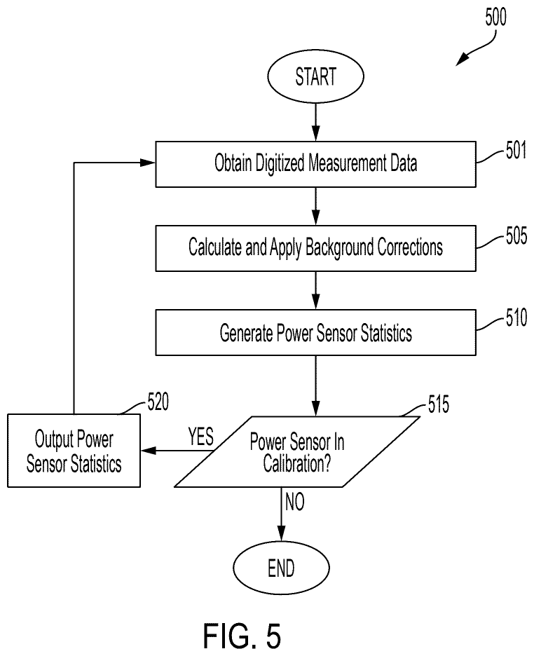

Turning to FIG. 5, a method 500 of operating power sensor 100 is shown in the form of an algorithm that is stored in memory 137 and executed by processor 136 of microcontroller 135 in power sensor 100 to determine the calibration condition of the power sensor 100, such as the calibration condition of the forward couplers 101a-n. It is contemplated that the same method (algorithm) can be used to determine the calibration condition of more components along the measurement chain, such as, but not limited to, the components of the forward coupler circuits 130a-c, such as forward couplers 101a-c, forward attenuators 105a-c, forward detectors 115a-c, and forward gain stages 120a-c. In exemplary embodiments where an individual analog to digital converter 125 is used for each forward coupler circuit 130a-c, then the forward coupler circuits 130a-c can also include the analog to digital converters.

To determine the calibration condition, in 501, the microcontroller 135 receives (obtains) digitized measurement data and stores the data in memory 137. The digitized measurement data can included digitized forward power measurement data from the analog to digital converter 125. The data is separated and stored in memory 137 for each forward coupler 101a-n of forward coupler circuits 130a-n. In some exemplary embodiments, there can be three forward coupler circuits 130a-c, with each circuit having a forward coupler 101a-c. It is contemplated that other exemplary embodiments of power sensor 100 can have more or less than three forward coupler circuits 130a-n and corresponding forward couplers a-n.

The digitized measurement data can also include digitized reflected power measurement data from the reflected coupler 102 of the reflected coupler circuit 131 (digitized reflected power measurement data) and digitized frequency measurement data corresponding to the frequency of the signal being measured on transmission line 165 from the non-directional coupler 103 and frequency downconverted by the prescaler 112 of the non-directional circuit 132. The digitized measurement data can also include digitized temperature data from the temperature sensor 140 (digitized temperature sensor 140 output), and digitized relative humidity data from the humidity sensor 142 (digitized humidity sensor 142 output) from the analog to digital converter. The digitized measurement data can also include the output from the RTC 180 provided directly to processor 136.

Following the obtaining of the digitized measurement data in 501, in 505, the digitized forward power measurement data is then retrieved from memory 137, and background corrections are applied to the digitized forward power measurement data using processor 136, and the background corrected forward power measurement data is stored in memory 137 by processor 136. The background corrections can include, but are not limited to, one or more of frequency, temperature, humidity, voltage standing wave, and center conductor position corrections. In an exemplary embodiment, frequency correction can be applied to the digitized forward power measurement data using the processor 136 by retrieving the digitized frequency measurement data provided by prescaler 112 and an applicable frequency characterization curve retrieved from memory 137, calculating the frequency correction using the digitized frequency measurement data and the frequency characterization curve, and applying the frequency correction to the digitized forward power measurement data.

In some exemplary embodiments of power sensor 100, the frequency characterization curve may take into consideration the position of the individual forward couplers 101a-n along the transmission line 165 for the given wavelength of the signal travelling on the transmission line 165, such that a unique frequency correction for each individual forward coupler circuit 130-a-n may be calculated by processor 136, saved in memory 137, and applied to the digitized forward power measurement data by processor 136.

Further, in some exemplary embodiments, since the position of each individual forward coupler 101a-n and reflected coupler 102 linearly along and rotationally around the transmission line 165 is known (spatial alignment of the forward couplers 101a-n and reflected coupler 102 on and around the transmission line 165), a unique voltage standing wave correction may be calculated by processor 136, saved in memory 137, and applied to the digitized forward power measurement data for each forward coupler 101a-n of each individual forward coupler circuit 130a-n by processor 136, based on the spatial position of each forward coupler 101a-n, the digitized forward power measurement data, and the digitized reflected power measurement data.

Further, in some exemplary embodiments, center conductor position correction may be calculated by processor 136, saved in memory 137, and applied to the digitized forward power measurement data by processor 136. In exemplary embodiments where the forward couplers 101a-n are spaced radially around the transmission line, each forward coupler 101a-n may be spaced apart radially in known positions from adjacent forward couplers 101a-n and a known distance from a center point 169 of transmission line 165, when viewed along the transmission line 165 from either the transmitter end (source end) 166 or load end (antenna end) 167. This radial placement of the forward couplers 101a-n around the transmission line 165 permits the power sensor 100 to measure and correct for uncertainty associated with mechanical movement of the center conductor 168 of transmission line 165.

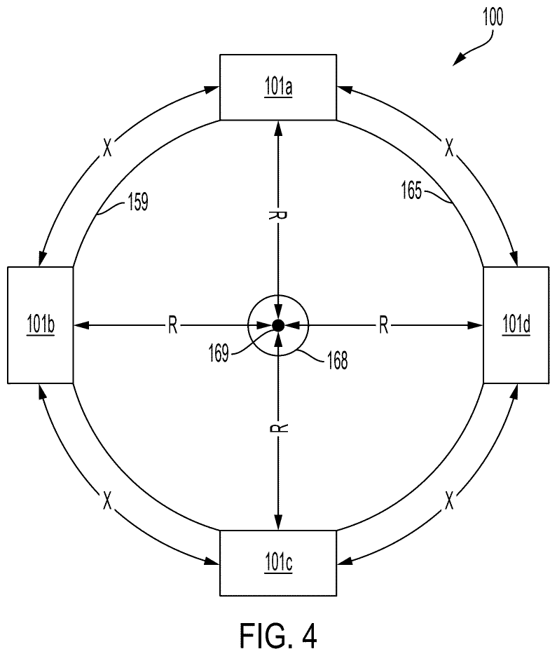

For example, in an exemplary embodiment where forward couplers 101a-d are equally spaced apart radially “X” degrees and a known distance equidistance (distance “R”) from a center point 169 of transmission line 165, such that forward coupler 101a and forward coupler 101c in the exemplary embodiment shown in FIG. 4 located 180 degrees from each other obtain power measurements that indicate a difference equal in magnitude but opposite in sign, such measurements would be indicative of a mechanical movement of center conductor 168, and the resulting uncertainty of the mechanical movement may be calculated, stored in memory 137, and a correction applied to the digitized forward power measurement data by microcontroller 135. Further, such radial symmetry of the forward couplers 101a-d, would, to the first order, cancel any error due to a mechanical shift between the center conductor 168 and outer conductor 159 of the transmission line 165 when the measurements of the forward couplers 101a-c, arranged in a radial symmetric configuration, are averaged together.

Further, in an exemplary embodiment, temperature correction can be applied to the digitized forward power measurement data using the processor 136 by retrieving the digitized temperature measurement data (digitized temperature sensor 140 output) and an applicable temperature characterization curve from memory 137, calculating the temperature correction using the digitized temperature measurement data and the temperature characterization curve, and applying the temperature correction to the digitized forward power measurement data.

Additionally, in an exemplary embodiment, humidity correction can be applied to the digitized forward power measurement data using the processor 136 by retrieving the digitized humidity measurement data (digitized humidity sensor 142 output) and an applicable humidity characterization curve from memory 137, calculating the humidity correction using the digitized humidity measurement data and the humidity characterization curve, and applying the humidity correction to the digitized forward power measurement data.

Once all of the background corrections are applied to the digitized forward power measurement data by processor 136, the background corrected forward power measurement data is then stored in memory 137 by processor 136.

Following 505, in 510, the background corrected forward power measurement data from the individual forward coupler circuits 130a-n is then retrieved from memory 137 and averaged by processor 136 to calculate an aggregate average forward power measurement. The processor 136 then stores the aggregate average forward power measurement in memory 137. The exemplary embodiment shown has three forward couplers 101a-c, however, it is contemplated that more or less than three forward couplers may be used in other exemplary embodiments of power sensor 100. In an exemplary embodiment, the aggregate average forward power measurement may be provided (outputted) by the power sensor 100 to a user as the forward power measurement value of power sensor 100 to the I/O device 161 by processor 136 using port 157.

The individual background corrected forward power measurements from the individual forward couplers 101a-n of the individual forward coupler circuits 130a-n are retrieved from memory 137 and compared using processor 136 to generate power sensor statistics, such as statistics related to the performance of the forward coupler circuits 130a-n. In an exemplary embodiment, the power sensor statistics can include, but are not be limited to, the aggregate average forward power measurement of all of the forward coupler circuits 130a-n. The power sensor statistics may also include any other values calculated in 510, such as, but not limited to, individual background corrected forward power measurements.

This aggregate average forward power measurement can be used to determine the percent difference between each individual background corrected forward power measurement and stored in memory 137. In an exemplary embodiment, to calculate the percent difference, Ma, Mb, Mc, . . . Mn are the individual forward power measurements for each forward coupler circuits 130a-n and Mavg is the aggregate average forward power measurement of the forward coupler circuits 130a-n then each percent difference magnitude of each individual forward coupler circuit 130a-n is calculated as Pn=ABS((Mn−Mavg)/Mavg)).

While some exemplary embodiments of power sensor 100 may use the percent difference between individual corrected forward power measurements of the individual forward coupler circuits 130a-n and the average aggregate measurement, as is detailed above, it is conceivable that other statistical methods can be employed to determine the variation between individual measurements of the forward coupler circuits 130a-n, the average aggregate measurement of the forward coupler circuits 130a-n, or other comparable measurements that comprise the power sensor statistics. Such methods may include, but are not limited to, standard deviation analysis, variance calculation, or other statistical tools that can provide insights into the consistency and accuracy of the measurements of the aggregate of and each individual forward coupler circuit 130a-n.

The magnitude of percent difference of each of the forward coupler circuits 130a-n is compared to a predetermined percent difference threshold to determine how many of the forward coupler circuits 130a-n are less than or equal to the predetermined percent difference threshold. The predetermined percent difference threshold may be determined by the accuracy specified for the power sensor 100. If the magnitude of the percent difference is greater than the predetermined percent difference threshold for more than a predetermined number of the forward coupler circuits 130a-n specified accuracy (predetermined out of calibration forward circuit threshold), then it is determined that calibration of the power sensor 100 is required (power sensor 100 is out of calibration).

For example, in an exemplary embodiment of power sensor 100 having three forward coupler circuits 130a-c, the predetermined out of calibration forward circuit threshold may be greater than or equal to two, and the predetermined percent difference threshold may be less than or equal to 3%. Thus, if the individual magnitude of the percent difference for at least two of the three forward coupler circuits 130a-c is greater than 3%, then the power sensor 100 is considered out of calibration and the out of calibration status is stored in memory 137 by processor 136. While three forward coupler circuits 130a-c are used in the above example, it is contemplated that other exemplary embodiments may use more or less forward couplers 101 (more or less forward coupler circuits 130a-c) to determine the calibration condition of the power sensor 100. It is also contemplated that more than just a single measurement of each forward coupler circuit 130a-n can be used to determine the calibration condition of the power sensor 100. It is contemplated that other statistical methods can be used in addition to those described above to determine the calibration condition of the power sensor 100.

Further, it is contemplated that in some exemplary embodiments of power sensor 100, any forward coupler circuits 130a-n that are out of calibration are identified and stored in memory 137 by processor 136 and power sensor 100 (processor 136) will exclude the outputs from any previously identified out of calibration forward coupler circuits 130a-n from inclusion in any future aggregate average forward power measurements.

Since the individual magnitude of the percent difference of each forward coupler circuit 130a-n is calculated by processor 136 and stored in memory 137, some exemplary embodiments of power sensor 100 also calculate the percent difference trend over time for each forward coupler circuit 130a-n to calculate using processor 136, as well as an estimate of when the power sensor 100 will be out of calibration (an estimated time until calibration) for a given predetermined percent difference threshold and a given predetermined out of calibration forward circuit threshold. This calculated estimate (estimated time until calibration is needed) is stored in in memory 137 may be retrieved from memory 137 using processor 136 and provided to the user, such as displayed to user via I/O device 161 or through port 157.

Further, in some exemplary embodiments of power sensor 100, the uncertainty of the power sensor may also be improved by removing from the aggregate average forward power measurement the output of any forward coupler circuits 130a-n that have a percent difference that exceeds the predetermined percent difference threshold, while the predetermined out of calibration forward circuit threshold is not exceeded. This can be accomplished by recalculating, using processor 136, the aggregate average forward power measurement using only the background corrected measurement data for the forward coupler circuits 130a-n that have a percent difference less than or equal to the predetermined percent difference threshold. This recalculated aggregate average forward power measurement may be stored in memory 137 by processor 136, and made available to the user, such as by being displayed to a user via I/O device 161 or through port 157.

The calibration status of the power sensor 100 is stored in memory 137. Thus, when it is determined that the power sensor 100 is out of calibration, the “out of calibration” status is stored in memory 137 by processor 136. Further, in 510, the output of the RTC 180 may be examined to determine if the if a predetermined recommended calibration time interval for the power sensor 100 has elapsed. In an exemplary embodiment where the output of the RTC 180 is a time value, the output of the RTC 180 may be compared to a time value stored in memory 137 by processor 136. The time value stored in memory 137 may be determined by the predetermined recommended calibration time interval and time of last calibration of power sensor 100. If the comparison by processor 136 of the output of RTC 180 and the time value stored in memory 137 indicate that the predetermined recommended calibration time interval has elapsed, then the “out of calibration” status is stored in memory 137 by processor 136.

In other exemplary embodiments of power sensor 100 where the RTC 180 itself determines when the predetermined recommended calibration time interval has elapsed and provides output indicative that the predetermined recommended calibration time interval has elapsed, the processor 136 looks at the output of the RTC 180 and stores the “out of calibration” status in memory 137, when the output of the RTC 180 indicates that the predetermined recommended calibration time interval has elapsed.

In exemplary embodiments where the power sensor 100 keeps track of the elapsed time since the previous (last) calibration and can determine if the recommended calibration interval has elapsed. This information can be used separately, or in conjunction with, the information obtained by the other aforementioned methods of determining calibration status, to determined when to indicate that a recalibration of the power sensor 100 is necessary (power sensor 100 is deemed out of calibration).

Following 510, in 515, the calibration status of power sensor 100 is examined in memory 137 by processor 136 and the user is informed of the calibration status of power sensor 100. In an exemplary embodiment, the user may be informed of the calibration status via one or more methods, such as by a specific illumination state/pattern of the LED 138, a status register of processor 136, accessed through port 157, and/or displayed to a user via I/O device 161. In some exemplary embodiments, the calibration status may be conveyed to the user via a flag, such as, but not limited to a flag within a standard commands for programmable instruments (SCPI) status register of processor 136 accessible via port 157. In other exemplary embodiments, the calibration condition may also be conveyed by power sensor 100 to the user via an asynchronous notification, a status register, or other suitable communication method. It is contemplated that a person having ordinary skill in the art will select a suitable method of conveying the calibration status to a user based on system design and user requirements.

Following 515, if the power sensor 100 is in calibration, then the power sensor statistics of power sensor 100 are provided to the user in 520, such as through I/O device 161 and the algorithm proceeds to 501. Further in 520, any other information saved in memory 137 can be outputted to a user, such as via port 157 and/or via I/O device 161. Such information may include, but is not limited to, digitized measurement data, background corrections, and output of the RTC 185.

Otherwise, following 515, if the power sensor 100 is not in calibration (out of calibration), the algorithm stops to permit the power sensor 100 to be calibrated.

As can be seen, in some exemplary embodiments, a radio frequency (RF) power sensor 100 having measurement uncertainty of less than about ±0.3% has been achieved through the use of cross-correlation for reduction of uncertainty. In other exemplary embodiments, the measurement uncertainty of less than about ±0.3% has been achieved using cross-correlation for reduction of uncertainty, as well as corrections for one or more of temperature, humidity, frequency, voltage standing waves, and center conductor position error (environmental corrections).

In some exemplary embodiments, the measurement uncertainty of less than about ±0.3% may also be achieved by calculating a forward power output of the power sensor 100 based on an aggregate average forward individual power measurement obtained from at least one forward power circuit 130a-n via at least one forward power coupler 101a-n. Further, in additional exemplary embodiments, the measurement uncertainty of less than about ±0.3% may further be achieved by excluding from the aggregate average forward power measurement, measurements from any forward power circuits 130a-n previously identified out of calibration, such as digitized forward power measurement data and background corrected forward power measurement data.

In some exemplary embodiments, the measurement uncertainty of less than about ±0.3% may also be achieved by determining if the predetermined recommended calibration interval has elapsed, and providing an output indicative that calibration is needed, when the predetermined recommended calibration interval has elapsed.

While this invention has been described with respect to particular embodiments thereof, it is apparent that numerous other forms and modifications of this invention will be obvious to those skilled in the art. The appended claims and this invention generally should be construed to cover all such obvious forms and modifications which are within the true spirit and scope of the present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as critical, required, or essential features or elements of any or all the claims. As used herein, the terms “comprises, “comprising,” or any other variation thereof, are intended to cover a non-exclusive inclusion, such that a process, method, article, or apparatus that comprises a list of elements does not include only those elements, but may include other elements not expressly listed or inherent to such process, method, article, or apparatus. Further, no element described herein is required for the practice of the invention unless expressly described as “essential” or “critical.” While this invention has been described in conjunction with the specific embodiments described above, it is evident that many alternatives, combinations, modifications and variations are apparent to those skilled in the art. Accordingly, the preferred embodiments of this invention, as set forth above are intended to be illustrative only, and not in a limiting sense. Various changes and combinations can be made without departing from the spirit and scope of this invention. Combinations of the above embodiments and other embodiments will be apparent to those of skill in the art upon studying the above description and are intended to be embraced therein. Therefore, the scope of the present invention is defined by the appended claims, and all devices, processes, and methods that come within the meaning of the claims, either literally or by equivalence, are intended to be embraced therein.

What is claimed is:

1. A radio frequency (RF) power sensor having a measurement uncertainty of less than about ±0.3%,
wherein the RE power sensor is a thru-line power sensor;
wherein the RF power sensor is comprised of at least three forward directional coupler circuits for measuring power on the transmission line;
wherein a voltage standing waves correction is applied to each of the individual measurements of the at least three forward directional coupler circuits,
the correction for the voltage standing waves is determined using a spatial position of a forward coupler of each the forward directional coupler circuits, the measurements of the forward directional coupler circuits, and a spatial position and a measurement of a reflected directional coupler of the RF power sensor.

2. The RF power sensor of claim 1, wherein the power sensor is configured to measure an RF power level greater than or equal to about 1 watt,
wherein the measurement uncertainty of less than about ±0.3% is achieved using cross-correlation.

3. The RF power sensor of claim 1, wherein the RF power sensor is comprised of a transmission line and at least one forward directional coupler circuit for measuring power on the transmission line using cross-correlation for reduction of uncertainty.

4. (canceled)

5. The RF power sensor of claim 118, wherein the RF power sensor calculates a percentage error magnitude for each of the at least three forward directional coupler circuits using the aggregate average forward power measurement and the individual measurements of the at least three forward directional coupler circuits.

6. The RF power sensor of claim 5, wherein the percentage error magnitude for each forward directional coupler circuit is compared to a predetermined percent difference threshold on an individual basis, wherein the forward directional coupler circuit is considered to be out of calibration, when the percentage error magnitude is greater than a predetermined percent difference threshold.

7. The RF power sensor of claim 6, wherein individual measurements from the out of calibration directional coupler circuits are excluded from the aggregate average forward power measurements.

8. The RF power sensor of claim 7, wherein the RF power sensor is considered to be out of calibration, when a number of forward coupler circuits considered to be out of calibration is greater than a predetermined out of calibration forward circuit threshold, and the RF power sensor informs a user when the RF power sensor is out of calibration.

9. The RF power sensor of 5, wherein the RF power sensor calculates a trend of the percentage error magnitudes over time to estimate a time until calibration of the RF power sensor is needed.

10. (canceled)

11. The RF power sensor of 119, wherein the environmental corrections additionally correct for one or more of temperature, humidity, frequency, and/or a center conductor position error of the transmission line.

12. The RF power sensor of claim 11, wherein:
the correction for the temperature is determined using a temperature sensor of the RF power sensor and a temperature characterization curve;
the correction for the humidity is determined using a humidity sensor of the RF power sensor and a humidity characterization curve;
the correction for frequency is determined using a non-directional coupler of the RF power sensor, a prescaler of the RF power sensor, and a frequency characterization curve; and
the center conductor position error correction is determined using a spatial position longitudinally along the transmission line and rotationally around the transmission line for each of the forward couplers of the forward directional coupler circuits, and the measurements of the forward directional coupler circuits.

13. The RF power sensor of claim 1 further comprising a real-time clock, wherein the RF power sensor uses the real-time clock to determine if a predetermined recommended calibration time interval has elapsed since a last calibration.

14. A method for making an RF power measurement comprising:
providing a power sensor having measurement uncertainty of less than about ±0.3%,
wherein the power sensor is a thru-line power sensor and the RF power sensor is comprised of at least three forward directional coupler circuits for measuring power on the transmission line;
obtaining individual measurements of the at least three forward directional coupler circuits;
applying a voltage standing waves correction to each of the individual measurements of the at least three forward directional couplers circuits,
wherein the correction for the voltage standing waves is calculated using a spatial position of a forward coupler of each the forward directional coupler circuits, the measurements of the forward directional coupler circuits, a spatial position and a measurement of a reflected directional coupler of the RF power sensor.

15. The method of claim 14, wherein the RF power sensor is comprised of a transmission line and at least one forward directional coupler circuit for measuring power on the transmission line, wherein cross-correlation is used to achieve the uncertainty of less than about ±0.3%.

16. (canceled)

17. The method of claim 120, further comprising:
calculating a percentage error magnitude for each of the at least three forward directional coupler circuits using the aggregate average forward power measurement and the individual measurements of the at least three forward directional coupler circuits.

18. The method of claim 17, further comprising:
comparing the percentage error magnitude for each forward directional coupler circuit to a predetermined percent difference threshold on an individual basis,
wherein the forward directional coupler circuit is considered to be out of calibration, when the percentage error magnitude is greater than a predetermined percent difference threshold.

19. The method of claim 18, further comprising:
excluding from the aggregate average forward power measurements, the individual measurements of the out of calibration directional coupler circuits.

20. The method of claim 19, further comprising:
wherein the RF power sensor is considered to be out of calibration, when a number of forward coupler circuits considered to be out of calibration is greater than a predetermined out of calibration forward circuit threshold, and
informing a user when the RF power sensor is out of calibration.

21. The method of claim 17, further comprising:
calculating a trend of the percentage error magnitudes over time to estimate a time until calibration of the RF power sensor is needed and
informing a user of the estimate of the time until calibration of the RF power sensor is needed.

22. (canceled)

23. The method of claim 121, wherein the environmental corrections further correct for one or more of temperature, humidity, frequency, and/or a center conductor position error of the transmission line.

24. The method of claim 23, wherein:
the correction for the temperature is calculated using a temperature sensor of the RF power sensor and a temperature characterization curve;
the correction for the humidity is calculated using a humidity sensor of the RF power sensor and a humidity characterization curve;
the correction for frequency is calculated using a non-directional coupler of the RF power sensor, a prescaler of the RF power sensor, and a frequency characterization curve; and
the center conductor position error correction is calculated using a spatial position longitudinally along the transmission line and rotationally around the transmission line for each of the forward couplers of the forward directional coupler circuits, and the measurements of the forward directional coupler circuits.

25. The method of claim 14, wherein the RF power sensor is further comprised of a real-time clock, the method further comprising using the real-time clock to determine if a predetermined recommended calibration time interval has elapsed since a last calibration.

26. An RF power sensor having a measurement uncertainty of less than about ±0.3%, comprising:
a transmission line;
at least three forward directional coupler circuits each of which having a forward coupler and a reflected directional coupler for measuring power on the transmission line;
a processor;
a memory communicatively connected to the processor, the memory storing instructions that, when executed by the processor, cause the processor to:
measure power on the transmission line with a measurement uncertainty of the less than about ±0.3%;
apply the correction for the voltage standing waves to each of the individual measurements of the at least three forward directional coupler circuits;
wherein the correction for the voltage standing waves is determined using a spatial position of a forward coupler of each the forward directional coupler circuits, the measurements of the forward directional coupler circuits, and a spatial position and a measurement of the reflected directional coupler of the RF power sensor;
wherein the RF power sensor is a thru-line power sensor.

27. The RF power sensor of claim 26, wherein the power sensor is configured to measure an RF power level greater than or equal to about 1 watt, wherein the measurement uncertainty of less than about ±0.3% is achieved using cross-correlation.

28. The RF power sensor of claim 26, further comprising at least one forward directional coupler circuit for measuring power on the transmission line using cross-correlation for reduction of uncertainty.

29. (canceled)

30. The RF power sensor of claim 122, the memory storing instructions that, when executed by the processor, cause the processor to:
calculate a percentage error magnitude for each of the at least three forward directional coupler circuits using the aggregate average forward power measurement and the individual measurements of the at least three forward directional coupler circuits.

31. The RF power sensor of claim 30, the memory storing instructions that, when executed by the processor, cause the processor to:
compare the percentage error magnitude for each forward directional coupler circuit to a predetermined percent difference threshold on an individual basis,
wherein the forward directional coupler circuit is considered to be out of calibration, when the percentage error magnitude is greater than a predetermined percent difference threshold.

32. The RF power sensor of claim 31, the memory storing instructions that, when executed by the processor, cause the processor to:
exclude from the aggregate average forward power measurements, the individual measurements of the out of calibration directional coupler circuits.

33. The RF power sensor of claim 32, wherein the RF power sensor is considered to be out of calibration, when a number of forward coupler circuits considered to be out of calibration is greater than a predetermined out of calibration forward circuit threshold,
the memory storing instructions that, when executed by the processor, cause the processor to:
inform a user when the RF power sensor is out of calibration.

34. The RF power sensor of claim 30, the memory storing instructions that, when executed by the processor, cause the processor to:
calculate a trend of the percentage error magnitudes over time to estimate a time until calibration of the RF power sensor is needed; and
inform a user of the estimate of the time until calibration of the RF power sensor is needed.

35. (canceled)

36. The RF power sensor of claim 123, wherein the environmental corrections further correct for one or more of temperature, humidity, frequency, and/or a center conductor position error of the transmission line.

37. The RF power sensor of claim 36, the memory storing instructions that, when executed by the processor, cause the processor to:
calculate the correction for the temperature using a temperature sensor of the RF power sensor and a temperature characterization curve;
calculate the correction for the humidity using a humidity sensor of the RF power sensor and a humidity characterization curve;
calculate the correction for frequency using a non-directional coupler of the RF power sensor, a prescaler of the RF power sensor, and a frequency characterization curve; and
calculate the center conductor position error correction using a spatial position longitudinally along the transmission line and rotationally around the transmission line for each of the forward couplers of the forward directional coupler circuits, and the measurements of the forward directional coupler circuits.

38. The RF power sensor of claim 26, wherein the RF power sensor is further comprised of a real-time clock, the memory storing instructions that, when executed by the processor, cause the processor to:
determine if a predetermined recommended calibration time interval has elapsed since a last calibration using the real-time clock.

39-117. (canceled)

118. The RF power sensor of claim 1, wherein the RF power sensor uses cross-correlation for reduction of uncertainty, wherein individual measurements of the at least three forward directional couplers circuits are averaged together, thereby producing an aggregate average forward power measurement and providing to a user as a forward power measurement of the RF power sensor.

119. The RF power sensor of claim 118, wherein at least one environmental correction is applied to each of the individual measurements of the at least three forward directional couplers circuits.

120. The method of claim 14, wherein the at least three forward directional coupler circuits for measuring power on the transmission line use cross-correlation for reduction of uncertainty,
wherein the method further comprises: averaging the individual measurements of the individual measurements of the at least three forward directional coupler circuits, thereby producing an aggregate average forward power measurement,
providing the aggregate average forward power measurement to a user as a forward power measurement of the RF power sensor.

121. The method of claim 120, further comprising:
applying at least one environmental correction to each of the individual measurements of the at least three forward directional couplers circuits.

122. The RF power sensor of claim 26, the memory storing instructions that, when executed by the processor, cause the processor to:
use cross-correlation for reduction of uncertainty;
calculate an aggregate average forward power measurement using individual measurements of the at least three forward directional couplers circuits; and
provide the aggregate average forward power measurement to a user as a forward power measurement of the RF power sensor.

123. The RF power sensor of claim 122, the memory storing instructions that, when executed by the processor, cause the processor to:
apply at least one environmental correction to each of the individual measurements of the at least three forward directional couplers circuits.
